(19) United States
(12) Patent Application Publication
(10) Pub. No.: US 2008/0088386 A1
(43) Pub. Date: Apr. 17, 2008

(54) JITTER GENERATING DEVICE AND PHASE MODULATING DEVICE

(75) Inventor: Minoru MAEDA, Musashino-shi (JP)

Correspondence Address: SUGHRUE-265550, 2100 PENNSYLVANIA AVE. NW, WASHINGTON, DC, 20037-3213, US

(73) Assignee: YOKOGAWA ELECTRIC CORPORATION, Musashino-shi (JP)

(21) Appl. No.: 11/870,507

(22) Filed: Oct. 11, 2007

(30) Foreign Application Priority Data
Oct. 11, 2006 (JP) 2006-277434

(51) Int. Cl. H03C 3/00

(52) U.S. Cl. 332/144

(57) ABSTRACT

A jitter generating device for generating a jitter on a carrier signal includes: a carrier signal generator for generating the carrier signal; a modulation signal generator for generating a modulation signal corresponding to the jitter; an orthogonal modulator for modulating a phase of the carrier signal generated by the carrier signal generator using the modulation signal generated by the modulation signal generator as one of modulation input signals; a DC power supply for applying a DC voltage serving as the other modulation input signal to the orthogonal modulator; and a limiter amplifier for setting an amplitude of an output signal of the orthogonal modulator to be constant.

This application is based on and claims priority from Japanese Patent Application No. 2006-277434, filed on Oct. 11, 2006, the entire contents of which are hereby incorporated by reference.

### BACKGROUND OF THE INVENTION

1. Technical Field

The present disclosure relates to a jitter generating device for generating a jitter on a carrier signal and a phase modulating device for modulating a phase of the carrier signal, and more particularly to a jitter generating device and a phase modulating device which have a broad band.

2. Related Art

For example, in a performance inspection of a communication device, a broadband jitter generating device has been required. For a related-art jitter generating device, as shown in FIG. 7A, there has been known a device that adds in an adder 23, a signal of a carrier signal generator 21 and that of a signal generator 22 having, as an oscillation frequency, a sum (ω+p) of a carrier signal frequency (ω) and a modulation signal frequency (p), and transmits the signal to a limiter amplifier 24, thereby obtaining a phase-modulated signal. For example, see APPENDIX WI of Non-Patent Document 1: ITU-T 0.172 (04/2005) Jitter and wander measuring equipment for digital system which are based on Synchronous Digital Hierarchy (SDH)

In the device shown in FIG. 7A, two high frequency signal generators, that is, the carrier signal generator 21 and the signal generator 22 are required. Both of them are to generate a carrier signal frequency or a signal having a high frequency which is close to the carrier signal frequency, and a cost and a space are required. In order to control a phase-modulated angle or a modulation index, moreover, it is necessary to control an amplitude of the high frequency signal in place of the modulation signal itself. Therefore, a technical burden is increased.

In the device shown in FIG. 7A, furthermore, an error from an original phase-modulated signal is present, FIG. 7B is a diagram showing, in a vector, a relationship between a carrier signal cos (ωt) and a modulation signal P=m·sin (pt).

As shown in FIG. 7B, the phase-modulated angle is obtained as follows:

θ=tan⁻¹{m·sin(pt)/(1+m·cos(pt))}.

A phase-modulated signal g(t) is obtained as follows:

g(t)=cos(ωt+ω)

=cos[ωt+tan⁻¹{m·sin(pt)/(1+m·cos(pt))}]

As is apparent from FIG. 7B or the above equations, when θ is increased (a modulation index of m is increased), an error (a phase modulation waveform distortion) from an original phase-modulated signal is increased:

f₀(t)=cos{ωt+m·sin(pt)}.

Moreover, it is a matter of course that a phase modulation can be applied by using an orthogonal modulator. In this case, when a carrier signal is represented by cos(ωt), a modulation signal is represented by sin(pt) and a time is represented by t, the modulated signal is obtained as follows:

cos{ωt+m·sin(pt)}.

The above equation is expressed as:

cos{ωt+m·sin(pt)}=cos(ωt)·cos{m·sin(pt)}−sin(ωt)·sin{m·sin(pt)}.

In the case in which a phase modulation of the modulation signal sin(pt) is applied by the orthogonal modulator, therefore, input signals I(t) and Q(t) are obtained as follows:

I(t)=cos{m·sin(pt)}

Q(t)=sin{m·sin(pt)}.

Consequently, both I(t) and Q(t) include an infinite harmonic content of a frequency p and it is hard to faithfully implement the I(t) and Q(t) signals.

### SUMMARY OF THE INVENTION

Exemplary embodiments provide a jitter generating device and a phase modulating device that can obtain a phase-modulated signal having a small modulating distortion at a low cost.

According to a first aspect of the present invention, a jitter generating device for generating a jitter on a carrier signal, comprises:

a carrier signal generator for generating the carrier signal;

a modulation signal generator for generating a modulation signal corresponding to the jitter;

an orthogonal modulator for modulating a phase of the carrier signal generated by the carrier signal generator using the modulation signal generated by the modulation signal generator as one of modulation input signals;

a DC power supply for applying a DC voltage serving as the other modulation input signal to the orthogonal modulator; and

a limiter amplifier for setting an amplitude of an output signal of the orthogonal modulator to be constant.

According to the jitter generating device, the carrier signal generated by the carrier signal generator is phase-modulated by the orthogonal modulator, and furthermore, the amplitude of the output signal is set to be constant by means of the limiter amplifier. Therefore, it is possible to obtain a phase-modulated signal having a small modulation distortion at a low cost.

According to a second aspect of the present invention, a jitter generating device for generating a jitter on a carrier signal, comprises:

a carrier signal generator for generating the carrier signal;

a modulation signal generator for generating a modulation signal corresponding to the jitter;

an orthogonal modulator for modulating a phase of the carrier signal generated by the carrier signal generator using the modulation signal generated by the modulation signal generator as one of modulation input signals;

a DC power supply for applying a DC voltage serving as the other modulation input signal to the orthogonal modulator;

a frequency multiplier disposed in a subsequent stage of the orthogonal modulator;

a band pass filter disposed in a subsequent stage of the frequency multiplier

According to a third aspect of the present invention, the jitter generating device may comprise:

a variable attenuator for attenuating the modulation signal, thereby generating said one of modulation input signals.

According to a fourth aspect of the present invention, the jitter generating device may comprise;

a change-over switch for changing over said one of modulation input signals between the modulation signal and an external signal.

According to a fifth aspect of the present inventions a phase modulating device for modulating a phase of a carrier signal, comprises:

a carrier signal generator for generating the carrier signal;

a modulation signal generator for generating a modulation signal;

an orthogonal modulator for modulating a phase of the carrier signal generated by the carrier signal generator using the modulation signal generated by the modulation signal generator as one of modulation input signals;

a DC power supply for applying a DC voltage serving as the other modulation input signal to the orthogonal modulator; and

a voltage correcting device for correcting a voltage value of the DC voltage synchronously with the modulation signal, so that an amplitude of a signal output from the orthogonal modulator comes to be constant.

According to the phase modulation generating device, the carrier signal generated by the carrier signal generator is phase-modulated by the orthogonal modulator, and furthermore, the voltage value of the DC voltage is corrected synchronously with the modulation signal, so that the amplitude of the signal output from the orthogonal modulator comes to be constant. Therefore, it is possible to obtain a phase-modulated signal having a small modulation distortion at a low cost.

According to the jitter generating device in accordance with the invention, the carrier signal generated by the carrier signal generator is phase-modulated by the orthogonal modulator, and furthermore, the amplitude of the output signal is caused to be constant by the limiter amplifier. Therefore, it is possible to obtain a phase-modulated signal having a small modulation distortion at a low cost.

According to the phase modulating device in accordance with the present invention, the carrier signal generated by the carrier signal generator is phase-modulated by the orthogonal modulator, and furthermore, the voltage value of the DC voltage is corrected synchronously with the modulation signal, so that the amplitude of the signal output from the orthogonal modulator comes to be constant. Therefore, it is possible to obtain a phase-modulated signal having a small modulation distortion at a low cost.

### BRIEF DESCRIPTION OF THE DRAWINGS

FIGS. 1A and 1B are diagrams showing a structure according to an exemplary embodiment of a phase modulating device in accordance with the present invention. FIG. 1A is a block diagram showing the structure according to the exemplary embodiment of the phase modulating device. FIG. 1B is a block diagram showing an example of a structure of an orthogonal modulator.

FIG. 2 is a vector diagram showing a phase-modulated signal over an I-Q plane.

FIGS. 3A and 3B are graphs showing a waveform distortion. FIG. 3A shows a calculation result of a waveform difference in a modulated phase angle θ with respect to a modulation signal P=m·sin(pt) in the phase modulating device according to the exemplary embodiment. FIG. 3B shows the same calculation result in a related-art device.

FIGS. 4A and 4B are diagrams showing another exemplary embodiment. FIG. 4A is a block diagram showing a structure in which a variable attenuator for varying a modulation index of the phase-modulated signal is provided. FIG. 4B is a block diagram showing a structure in which a change-over switch is provided between a modulation signal generator 2 and a Q terminal of an orthogonal modulator 3.

FIGS. 5A and 5B are diagrams showing another exemplary embodiment. FIG. 5A is a block diagram showing a structure in which a frequency multiplier is provided on an output side of the orthogonal modulator 3. FIG. 5B is a block diagram showing a structure in which a phase modulation waveform distortion is suppressed by a correction signal.

FIG. 6 is a vector diagram showing a phase-modulated signal over the I-Q plane according to the structure of FIG. 5B.

FIGS. 7A and 7B are diagrams showing a related-art device. FIG. 7A is a block diagram showing a structure of the related-an device. FIG. 7B is a vector diagram showing a relationship between a carrier signal and a modulation signal.

### DETAILED DESCRIPTION OF EXEMPLARY EMBODIMENTS

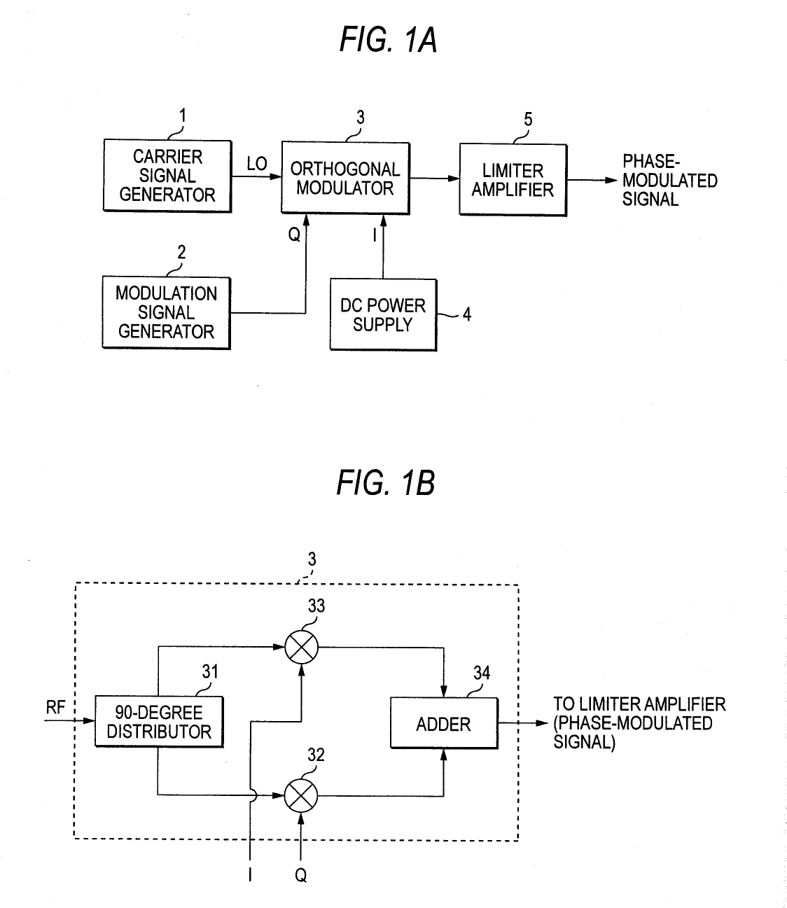

An exemplary embodiment of a phase modulating device according to the invention will be described below with reference to FIGS. 1 to 6.

FIG. 1A is a block diagram showing a structure according to an exemplary embodiment of the phase modulating device in accordance with the present invention.

As shown in FIG. 1A, a phase modulating device according to the exemplary embodiment includes: a carrier signal generator 1 for outputting a carrier signal having a frequency ω; a modulating signal generator 2 for outputting a modulation signal P=m·sin(pt); an orthogonal modulator 3; a DC power supply 4 for applying a DC voltage to the orthogonal modulator 3; and a limiter amplifier 5 (amplitude adjustment means) for amplifying a signal output from the orthogonal modulator 3 and adjusting an amplitude thereof to be constant.

As shown in FIG. 1A, the carrier signal transmitted from the carrier signal generator 1 is input to an LO input terminal of the orthogonal modulator 3. The modulation signal transmitted from the modulation signal generator 2 is input to a Q terminal of the orthogonal modulator 3. The DC voltage applied from the DC power supply 4 is input to an I terminal of the orthogonal modulator 3. The inputs to the Q and I terminals of the orthogonal modulator 3 may be replaced with each other.

FIGS. 1B is a block diagram showing an example of a structure of the orthogonal modulator 3. As shown in FIG. 1B, the orthogonal modulator 3 is constituted by a 90-degree distributor 31 for receiving the carrier signal, a double balanced mixer 32 for receiving one of output signals of the 90-degree distributor 31 and the modulation signal, a double balanced mixer 33 for receiving the other output signal of the 90-degree distributor 31 and the DC voltage, and an adder 34 for adding signals output from the double balanced mixer 32 and the double balanced mixer 33. The orthogonal modulator 3 can be obtained inexpensively in combination of components of the respective elements or as an IC put on the market.

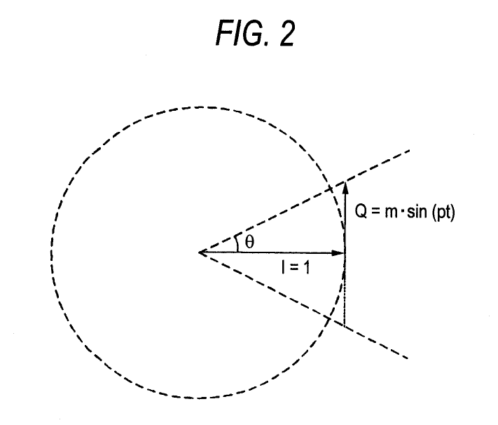

FIG. 2 is a vector diagram showing a signal output from the orthogonal modulator 3 (a phase-modulated signal) over an I-Q plane. For simplicity, an I vector length is set to be one in FIG. 2.

As shown in the vector diagram of FIG. 2, a phase-modulated angle θ and a phase-modulated signal f(t) are expressed in the following equation:

θ=tan⁻¹{m·sin(pt)}

f(t)=cos{ωt+tan⁻¹(m·sin(pt))}

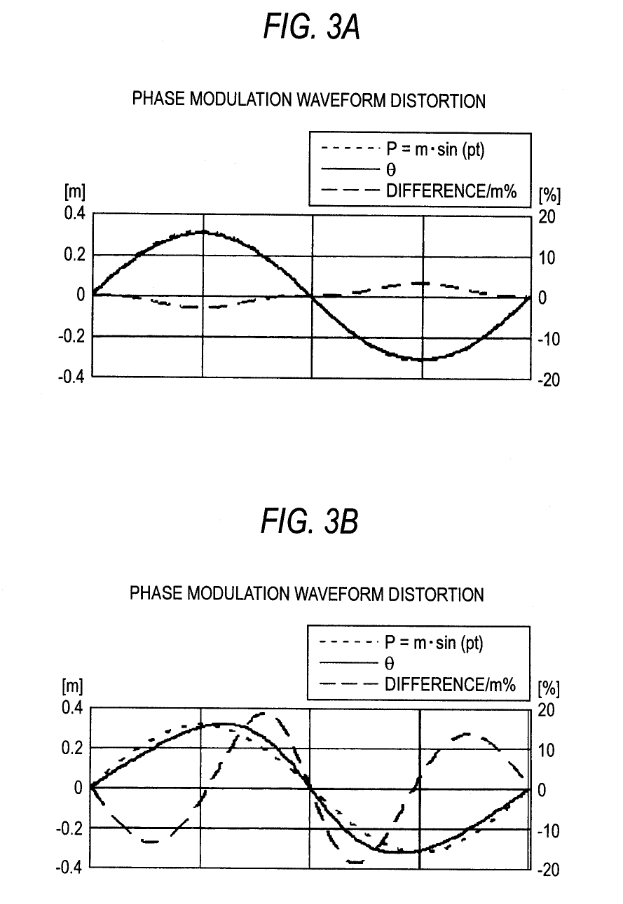

FIG. 3A shows a calculation result of a waveform difference in the phase-modulated angle θ with respect to a modulation signal P=m·sin(pt). FIG. 3A displays the modulation signal P=m·sin(pt), the phase-modulated angle θ, and furthermore, the waveform difference (a phase modulation waveform distortion). The case of a modulation index m=0.1π[rad] is shown.

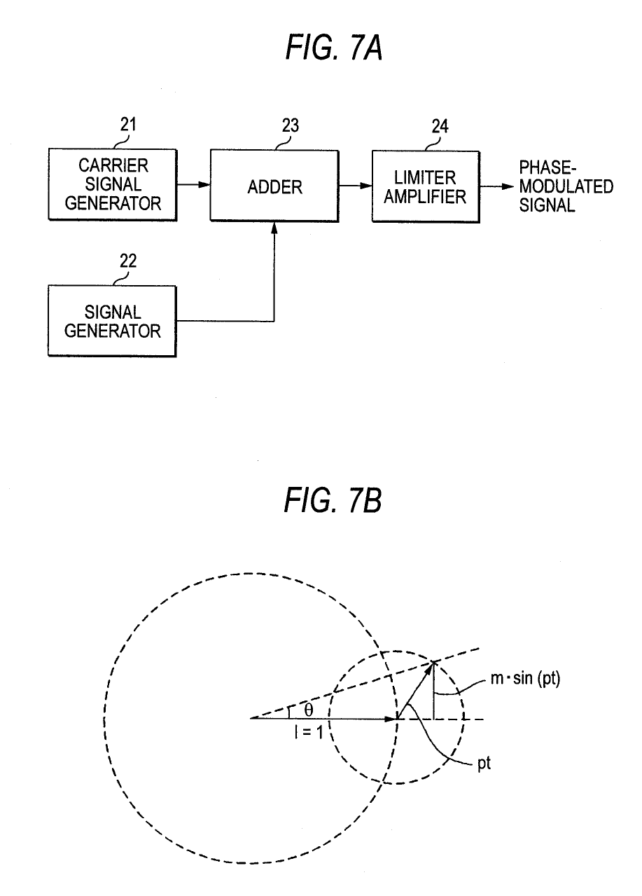

On the other hand, FIG. 3B shows the same calculation result in a related-art device illustrated in FIG. 7A. In the same manner as FIG. 3A FIG. 313 displays a modulation signal P=m·sin(pt), a phase-modulated angle θ, and the waveform difference in the case of a modulation index m=0.1π[rad].

As is apparent from a comparison between FIGS. 3A and 3B, the phase modulation waveform distortion is considerably reduced in the phase modulating device according to the exemplary embodiment as compared with the related-art device.

As described above, in the phase modulating device according to the exemplary embodiment, only the carrier signal generator 1 is used as a high frequency signal generator for generating a signal having a high frequency. Compared with the related-art device using two high frequency signal generators, therefore, a cost and a size of the device can be reduced considerably. Moreover, it is possible to control the phase modulation waveform distortion.

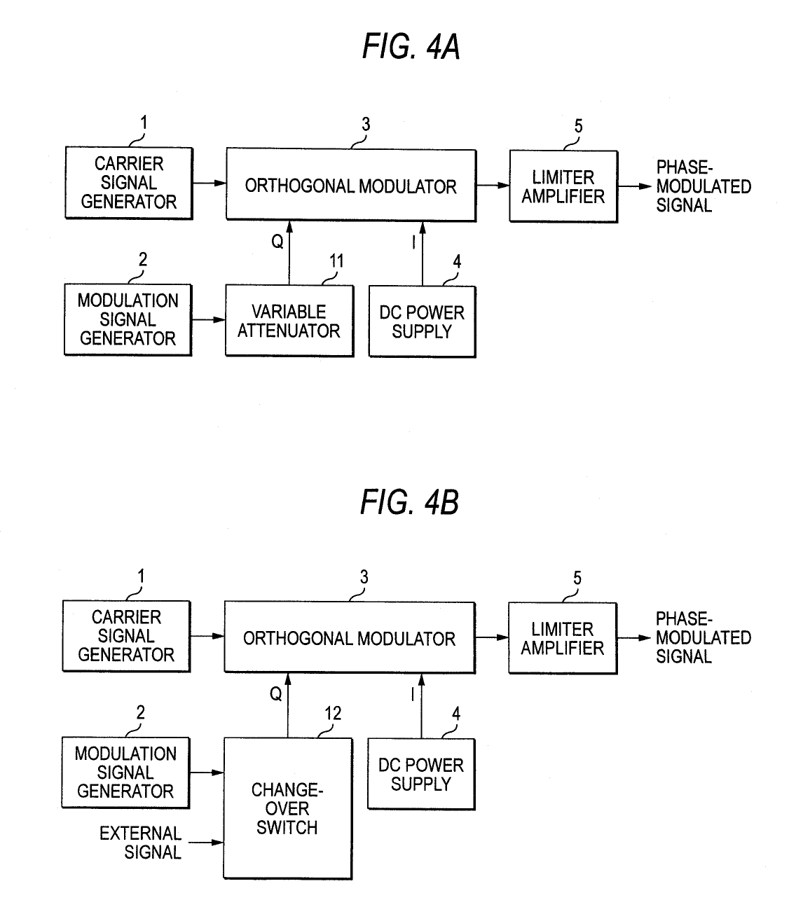

FIG. 4A is a block diagram showing a structure in which a variable attenuator for varying a modulation index of a phase-modulated signal is provided,

In an example shown in FIG. 4A, a variable attenuator 11 is inserted between the modulation signal generator 2 and the Q terminal of the orthogonal modulator 3. By controlling an amplitude of the modulation signal through the variable attenuator 11, it is possible to vary a modulation index. Therefore, it is possible to easily control the modulation index without adjusting a gain of the high frequency signal as in the related-art device (FIGS. 7A and 7B).

FIG. 4B is a block diagram showing a structure in which a change-over switch is provided between the modulation signal generator 2 and the Q terminal of the orthogonal modulator 3.

In an example of FIG. 4B, the modulation signal and an external signal can be optionally selected as a signal to be input to the Q terminal of the orthogonal modulator 3 by means of a change-over switch 12. Therefore, it is possible to utilize the device as a general-purpose phase modulator.

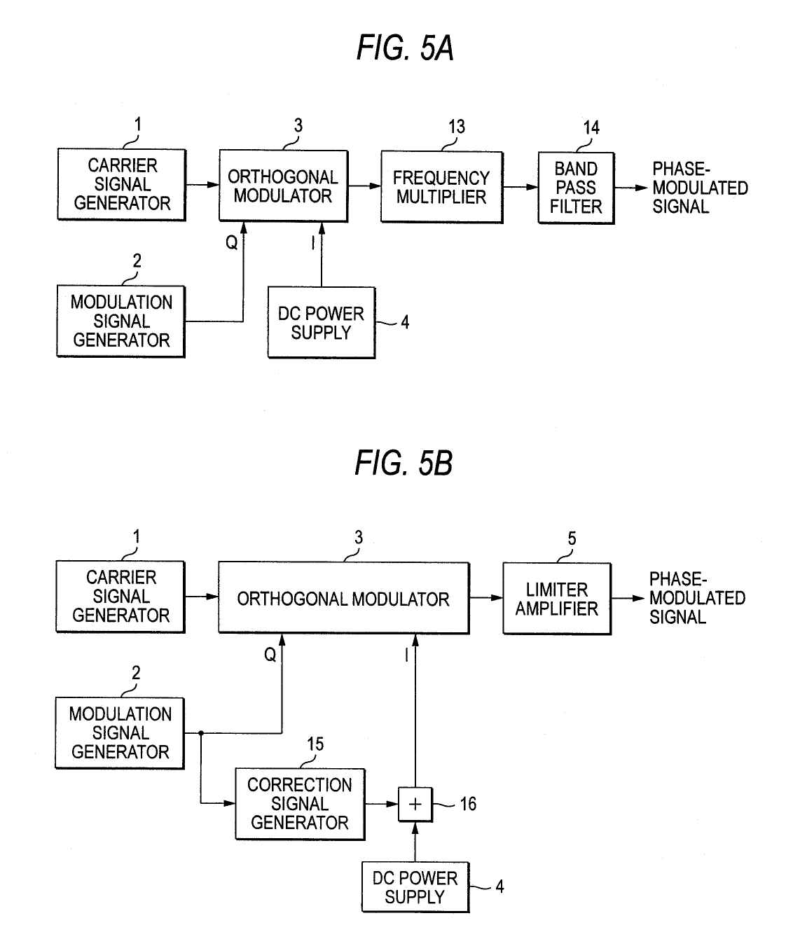

FIG. 5A is a block diagram showing a structure in which a frequency multiplier is provided on an output side of the orthogonal modulator 3.

In an example of FIG. 5A, a frequency multiplier 13 is connected to the output side of the orthogonal modulator 3, and furthermore, a signal transmitted from the frequency multiplier 13 is output through a band pass filer 14 so that a phase-modulated signal having a frequency corresponding to a multiple and a certain amplitude can be obtained.

FIG. 5B is a block diagram showing a structure in which a phase modulation waveform distortion is suppressed by a correction signal.

In an example of FIG. 5B, a correction signal based on a modulation signal is generated in a correction signal generator 15 and is added to a DC voltage applied from the DC power supply 4 in an adder 16, and a result obtained by the addition is given to the I terminal of the orthogonal modulator 3.

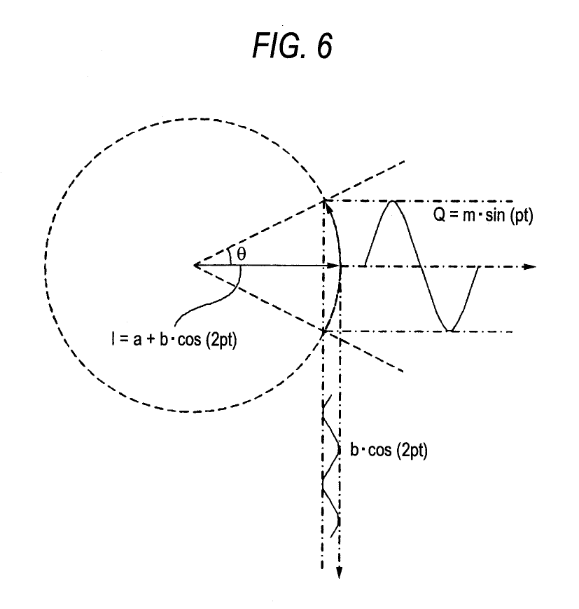

The correction signal may be set to a sine wave (b·cos(2pt)) having a frequency which is a double of a frequency of the modulation signal. FIG. 6 is a vector diagram showing a phase-modulated signal in this case over an I-Q plane. As shown in FIG. 6, a resultant vector obtained by I and Q signals approaches a circumference by the correction signal. Therefore, it is possible to further suppress the phase modulation waveform distortion to be a difference between θ and m·sin(pt).

The coverage of the present invention is not limited to the above-described exemplary embodiments. A phase modulating device according to the invention can be applied to wide uses without a limitation to an application to the jitter generating device. Moreover, it is also possible to optionally combine a plurality of components in the serial exemplary embodiment.

What is claimed is:

1. A jitter generating device for generating a jitter on a carrier signal, comprising:
a carrier signal generator for generating the carrier signal;
a modulation signal generator for generating a modulation signal corresponding to the jitter;
an orthogonal modulator for modulating a phase of the carrier signal generated by the carrier signal generator using the modulation signal generated by the modulation signal generator as one of modulation input signals;
a DC power supply for applying a DC voltage sewing as the other modulation input signal to the orthogonal modulator; and
a limiter amplifier for setting an amplitude of an output signal of the orthogonal modulator to be constant,

2. A jitter generating device for generating a jitter on a carrier signal, comprising:
a carrier signal generator for generating the carrier signal,
a modulation signal generator for generating a modulation signal corresponding to the jitter;
an orthogonal modulator for modulating a phase of the carrier signal generated by the carrier signal generator using the modulation signal generated by the modulation signal generator as one of modulation input signals;
a DC power supply for applying a DC voltage serving as the other modulation input signal to the orthogonal modulator;
a frequency multiplier disposed in a subsequent stage of the orthogonal modulator;
a band pass filter disposed in a subsequent stage of the frequency multiplier.

3. The jitter generating device according to claim 1, further comprising:
a variable attenuator for attenuating the modulation signal, thereby generating said one of modulation input signals.

4. The jitter generating device according to claim 1, further comprising:
a change-over switch for changing over said one of modulation input signals between the modulation signal and an external signal.

5. A phase modulating device for modulating a phase of a carrier signal, comprising:
a carrier signal generator for generating the carrier signal;
a modulation signal generator for generating a modulation signal;
an orthogonal modulator for modulating a phase of the carrier signal generated by the carrier signal generator using the modulation signal generated by the modulation signal generator as one of modulation input signals;
a DC power supply for applying a DC voltage serving as the other modulation input signal to the orthogonal modulator; and
a voltage correcting device for correcting a voltage value of the DC voltage synchronously with the modulation signal, so that an amplitude of a signal output from the orthogonal modulator comes to be constant.
